(19) United States
(12) Patent Application Publication
(10) Pub. No.: US 2026/0327439 A1
(43) Pub. Date: Oct. 22, 2026

(54) Laminated Body and Method for Producing Laminated Body

(71) Applicant: NIKON CORPORATION, Tokyo (JP)

(72) Inventors: Yasutaka NISHI, Tokyo (JP); Ryoko SUZUKI, Yokohama-shi (JP); Yoshiaki KITO, Kamakura-shi (JP)

(73) Assignee: NIKON CORPORATION, Tokyo (JP)

(21) Appl. No.: 19/576,826

(22) Filed: Mar. 24, 2026

Related U.S. Application Data
(63) Continuation of application No. PCT/JP2023/034933, filed on Sep. 26, 2023.

(51) Int. Cl. C09D 5/24; C09D 1/00; H01B 5/14

(52) U.S. Cl. CPC C09D 5/24; C09D 1/00; H01B 5/14

(57) ABSTRACT

Provided is a laminated body 1a comprising a substrate layer 10; a layer 121 containing first conductive particles on the substrate layer 10; and a layer 122 containing second conductive particles on the layer 121 containing the first conductive particles, wherein an average particle diameter of the first conductive particles is larger than an average particle diameter of the second conductive particles.

### CROSS REFERENCE TO RELATED APPLICATIONS

This application is a continuation application, filed under 35 U.S.C. § 111(a), of International Application No. PCT/JP2023/034933, filed Sep. 26, 2023, the contents of each of which are incorporated herein by reference.

### TECHNICAL FIELD

The present invention relates to a laminated body and a method for producing a laminated body.

### Background Art

Patent Document 1 discloses a technology for obtaining conductive ITO (indium tin oxide) particles by adding an indium source and a tin source to a solution in which a hydroxide of a quaternary ammonium ion is dissolved in a reducing organic solvent, causing a reaction, and then heating the solution in an autoclave to mature it under autogenous pressure.

### PRIOR ART DOCUMENTS

### Patent Document

PTL 1: Japanese Patent No. 5706797

### SUMMARY OF THE INVENTION

A first aspect of the present invention is a laminated body comprising a substrate layer, a layer including first conductive particles on the substrate layer, and a layer including second conductive particles on the layer including the first conductive particles, wherein the average particle diameter of the first conductive particles is larger than the average particle diameter of the second conductive particles.

A second aspect of the present invention is a laminated body comprising a support layer, a layer including second conductive particles on the support layer, and a layer including first conductive particles on the layer including the second conductive particles, wherein the average particle diameter of the second conductive particles is smaller than the average particle diameter of the first conductive particles.

A third aspect of the present invention is a method for producing a laminated body comprising a first layer and a second layer, the method comprising: supplying a first solution including first conductive particles onto a substrate layer or a support layer and drying the solvent contained in the first solution to form the first layer; and supplying a second solution including second conductive particles onto the first layer and drying the solvent contained in the second solution to form the second layer, wherein the average particle diameters of the first conductive particles and the second conductive particles are different from each other.

### BRIEF DESCRIPTION OF THE DRAWINGS

FIG. 1 is a schematic diagram illustrating an example of a laminated body according to the present embodiment.

FIG. 2 is a schematic diagram illustrating an example of an EL device using the laminated body according to the present embodiment.

FIG. 3 is a schematic diagram illustrating an example of a solar cell using the laminated body according to the present embodiment.

FIG. 4 is a schematic diagram illustrating another example of a laminated body according to the present embodiment.

FIG. 5 is a schematic diagram illustrating another example of an EL device using the laminated body according to the present embodiment.

FIG. 6 is a schematic diagram illustrating another example of a solar cell using the laminated body according to the present embodiment.

### DESCRIPTION OF EMBODIMENTS

Hereinafter, embodiments for carrying out the present invention (hereinafter simply referred to as “the present embodiment”) will be described in detail. The present embodiments are illustrative examples for explaining the present invention and are not intended to limit the present invention to the following content. In the drawings, identical elements are designated by the same reference numerals, and duplicate explanations are omitted. In addition, positional relationships such as up, down, left, and right are based on the positional relationships shown in the drawings unless otherwise specified. Further, the dimensional ratios in the drawings are not limited to the illustrated ratios.

### Laminated Body 1

A first aspect of the laminated body according to the present embodiment comprises a substrate layer, a first conductive layer including first conductive particles on the substrate layer, and a second conductive layer including second conductive particles on the first conductive layer, wherein the average particle diameter of the first conductive particles is larger than that of the second conductive particles. Such a laminated body can suppress contact resistance and interfacial resistance and is suitably used as a member of electroluminescent (EL) devices, solar cells, and the like.

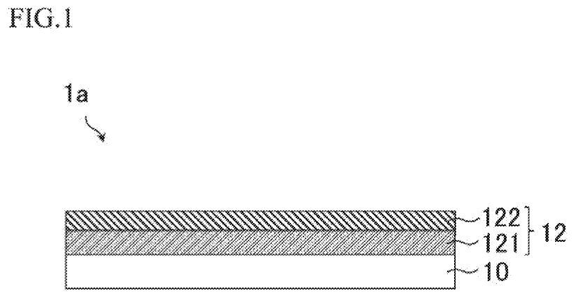

FIG. 1 is a schematic diagram illustrating an example of a laminated body according to the present embodiment.

The laminated body 1a has, on the substrate layer 10, a first conductive layer 121 including first conductive particles and a second conductive layer 122 including second conductive particles, formed in this order. The average particle diameter of the first conductive particles is larger than that of the second conductive particles. That is, the laminated body 1a has a conductive layer 12 formed on the substrate layer 10.

The term “average particle diameter” as used herein refers to the average of the diameters of primary particles, which is calculated by a dynamic light scattering method.

The average particle diameter of the first conductive particles is preferably 40-100 nm, more preferably 40-70 nm, and even more preferably 40-60 nm.

The average particle diameter of the second conductive particles is preferably 5-30 nm, more preferably 5-20 nm, and even more preferably 5 -15 nm.

The ratio of the average particle diameter of the first conductive particles to that of the second conductive particles is preferably 1.3-20, more preferably 1.3-14, and even more preferably 1.3-12.

The thickness of the first conductive layer is preferably 10-1000 nm, more preferably 10-100 nm, and even more preferably 10-20 nm.

The thickness of the second conductive layer is preferably 10-1000 nm, more preferably 10-100 nm, and even more preferably 10-20 nm.

The types of the first and second conductive particles (hereinafter collectively referred to as “conductive particles”) include, for example, tin-doped indium oxide (ITO) particles, antimony-doped tin oxide (ATO) particles, phosphorus-doped tin oxide (PTO) particles, tin oxide (TO) particles, titanium oxide particles, zinc oxide particles, other white conductive particles, and colorless conductive particles. These may be used alone or in combination of two or more types. Among these, it is preferable that the conductive particles are selected from one or more of ITO particles, ATO particles, PTO particles, and TO particles, and more preferably are ITO particles.

The material of the substrate layer 10 is not particularly limited, and a material usable as a substrate of the aforementioned EL devices, solar cells, and the like can be used. In particular, when performing a manufacturing method in which a dispersion is applied to the substrate layer 10 as described later, the material restriction is relaxed, allowing the use of a thin and highly flexible film substrate (also referred to as a sheet substrate). Furthermore, continuous production such as roll-to-roll can be performed. From this viewpoint, materials for the substrate layer 10 include, for example, glass, silicon, aluminum, alumina, polyethylene terephthalate (PET), polyethylene naphthalate (PEN), polyethersulfone (PES), polyetherimide, polyetheretherketone, polyphenylene sulfide, polyarylate, polyimide, polycarbonate (PC), cellulose triacetate (TAC), and cellulose acetate propionate (CAP).

Members such as semiconductors used in EL devices or solar cells are required to have low resistance. In this respect, in the laminated body 1a according to the present embodiment, by forming a structure in which first conductive particles having a large average particle diameter are laminated on the substrate layer 10, the number of contact points between the substrate layer and the conductive layer can be reduced, thereby reducing interfacial resistance at the interface between the substrate layer and the conductive film. In the conductive film, by laminating second conductive particles having a smaller average particle diameter on top of the first conductive particles having a larger average particle diameter, the contact area between particles can be increased, thereby reducing contact resistance between conductive particles. Thus, the laminated body 1a can reduce interfacial resistance and contact resistance, thereby exhibiting high conductivity.

It is preferable that the first conductive particles, the second conductive particles, or both satisfy the following relationship (1):

16×S/P²≤0.330 (1)

(where S represents the particle area in a TEM image and P represents the perimeter of the particle).

The particle area S and perimeter P in formula (1) are the particle area and perimeter in a TEM image, and can be obtained, for example, by the following method.

First, a TEM image of the conductive particles is processed using image processing software “ImageJ 1.5K.” For example, the target image is first imported and converted to 8-bit grayscale, and then the scale per pixel is set using “Set Scale” to correspond to the actual size in nanometers.

Next, to clarify the shape of the particles, “Enhance Contrast” is used to set the saturated pixels to about 20-40%. This value affects the contrast of the entire image and is adjusted as appropriate, for example, to a degree that the particle contours become clear. Further, binarization is performed using “Threshold” to separate particles from other areas, and the threshold can be set using the algorithm called “Moments.”

Then, “Analyze Particles” is selected to measure particle shape. In the measurement, by setting “Size (Pixels²)” to 1000-Infinity, contamination and background noise can be eliminated. The obtained “Area” and “Perim.” values can be regarded as the particle area S and particle perimeter P in the TEM image, respectively.

The value of particle area S in the present embodiment is not particularly limited and may be, for example, 100-4500 nm², or 200-4300 nm². The value of P is not particularly limited and may be, for example, 100-1200 nm, or 120-1000 nm.

The upper limit of the left-hand side of formula (1) may be 0.330 or less, preferably 0.300 or less, more preferably 0.280 or less, even more preferably 0.260 or less, and most preferably 0.250 or less. Within this range, the particle shape can be made largely different from a substantially rectangular shape. The lower limit of the left-hand side of formula (1) is not particularly limited and may be greater than 0, for example, 0.040 or more, 0.060 or more, 0.070 or more, or 0.100 or more.

The conductive particles according to the present embodiment can achieve uniform micronization, high dispersibility, and meet various requirements as materials for transparent electrodes, such as low resistance, high transmittance, and low haze.

Conventional conductive particles such as ITO particles are synthesized by the sol-gel method, and their particle shape is substantially rectangular. In the sol-gel method, nucleation and growth reactions occur within a gel network, so ITO particles produced by the sol-gel method have a rectangular shape reflecting the crystal phase and exhibit high crystallinity.

When forming a conductive film using conventional substantially rectangular conductive particles, if the particles are arranged such that their faces contact each other, the theoretical filling factor of the film can be 100%. Therefore, it was considered preferable for conductive particles to approach a single-crystal structure of a rectangular shape. However, as a result of diligent research by the inventors, it was found that in practice, particles are randomly packed and contact each other at points or lines. In such an arrangement, when used as a transparent conductive film, the conductive paths decrease and the resistance increases. In addition, if dispersibility is low, aggregation reduces filling factor and film smoothness. The present inventors recognized that conventional conductive particles have room for improvement in this regard.

The inventors further conducted investigations focusing on the macroscopic state of the conductive particles. As a result, it was found that the conductive particles according to the present embodiment can exhibit the above-described effects when satisfying the relationship of formula (1). Although the mechanism of this effect is not certain, it is believed that maintaining high crystallinity while reducing the maximum contact area results in good dispersibility in the liquid when the particles are prepared as a dispersion (however, the effects in the present embodiment are not limited to these).

The method for preparing the conductive particles is not particularly limited, and publicly known methods can be appropriately employed. As an example, the preparation of ITO particles will be described.

Regarding the composition of ITO particles, the molar ratio of Sn to In (Sn/In) is not particularly limited. However, from the viewpoints of crystal synthesis and conductivity, it is preferably 3.5-24, more preferably 3.7-23.5, and even more preferably 4-23.

In the present embodiment, when using ITO particles satisfying formula (1), it is preferable to produce the particles not by the sol-gel method but by the following method. That is, (a) a reaction step of reacting an In salt at 0.09-0.9 M (M =mol/L), an Sn salt at 0.01-0.2 M (M =mol/L), a basic compound, and a solvent in solution at 190-200 °C for 12-120 hours to obtain ITO particles, and (b) a step of washing the ITO particles.

The concentration of the In salt in the reaction solution is preferably 0.09-0.9 M, more preferably 0.09-0.45 M. The concentration of the Sn salt in the reaction solution is preferably 0.01-0.2 M, more preferably 0.01-0.05 M.

The concentration of the In salt is preferably 4.5-9 times, more preferably 5-9 times, the concentration of the Sn salt on a molar basis. By performing the particle synthesis reaction at such metal source concentrations, the ITO particles according to the present embodiment can be more easily synthesized in a one-pot process.

The In salt is not particularly limited, and any known In salt can be used as a raw material for ITO. For example, at least one selected from the group consisting of metal salts such as InCl₃, In₂(C₂O₄)₃, In(NO₃)₃, In₂(SO₄)₃, and hydrates of any of these salts can be used. Among these, anhydrous salts or metal salts are preferable, metal salts are more preferable, and InCl₃ is even more preferable.

The Sn salt is not particularly limited, and any known Sn salt as a raw material for ITO can be used. For example, at least one selected from the group consisting of metal salts such as SnCl₂, SnCl₄, Sn₂(C₂O₄)₃, Sn(NO₃)₂, and SnSO₄, and hydrates of any of these salts can be used. Among these, anhydrous salts and metal salts are preferred, metal salts are more preferred, and SnCl₂ and SnCl₄ are even more preferred.

As the basic compound, any compound capable of neutralizing the reaction solution to precipitate an In-Sn hydroxide (co-precipitation) may be used. Publicly known basic compounds may be employed, for example, tetramethylammonium hydroxide (TMAH), sodium hydroxide, and the like.

The concentration of the basic compound in the reaction solution is not particularly limited, but from the viewpoint of particle synthesis, 1-2 M is preferable, and 1.5-1.7 M is more preferable.

As the solvent, any solvent capable of dissolving the In salt, Sn salt, basic compound, and optionally used additives may be used. Publicly known solvents can be used, for example, water; alcohols such as methanol, ethanol, and isopropanol are preferable.

In the reaction step (a), other additives may be added if necessary, as long as they do not inhibit the effects of the present embodiment.

The reaction time in the reaction step (a) is preferably 12-120 hours, more preferably 24-72 hours.

The reaction temperature in the reaction step (a) is preferably 190-200 °C.

The reaction in the reaction step (a) may be carried out under open conditions, but it is preferable to use an autoclave. This can promote the formation of co-precipitated indium hydroxide-tin hydroxide in the reaction system.

The mechanism by which ITO particles satisfying formula (1) are obtained by the above-described production method is uncertain, but it is considered that control of the metal salt concentration (M=mol/L), reaction temperature, and reaction time in the system has an influence. The shape control of monodisperse particles can be governed by the number of nuclei generated and the amount of material present, and it is considered necessary to further induce heterogeneous nucleation on the nuclei while maintaining them in the gel network. Therefore, a high concentration of the metal source and a relatively small amount of base are preferable. This can maintain the concentration of metal oxide precursors available for nucleation for a long period. By combining the above conditions, synthesis is considered possible (however, the effects of the present embodiment are not limited to these).

To produce ITO particles satisfying formula (1), it is preferable to have a high concentration of the metal source and a relatively low base concentration relative to the metal source. This allows heterogeneous nucleation to proceed on the already formed nuclei, rather than particle growth after initial nucleation, thereby enabling synthesis of ITO particles satisfying formula (1).

In the present embodiment, it is preferable to perform a centrifugation step between the reaction step (a) and the washing step (b). As a centrifugation step, it is preferable to perform at 14,000 rpm for 10 minutes.

In the washing step (b) of the ITO particles, washing is preferably performed using water, ethanol, or other alcohols. When washing with water, distilled water or ion-exchanged water (IEW) is preferable. It is also preferable to treat the dispersion with an ultrasonic cleaner for washing.

Conventionally, after the reaction step, freeze-drying and reduction firing steps are performed. In the present embodiment, these are not necessary. From this viewpoint, it is particularly preferable not to perform a firing step after the washing step (b). This can prevent aggregation of the ITO particles and maintain a monodisperse state in the dispersion medium.

The laminated body 1a can be used as a low-resistance electronic component and can be used in EL devices and solar cells including the same.

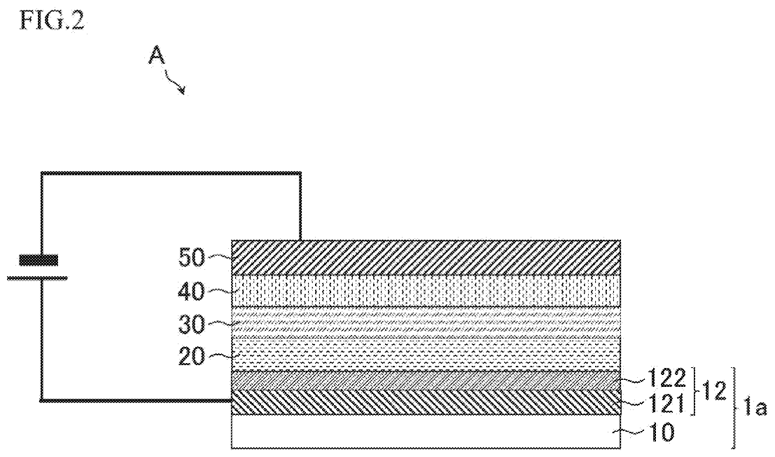

FIG. 2 is a schematic diagram illustrating an example of an EL device using the laminated body according to the present embodiment.

The EL device A has, on the second conductive layer 122 of the laminated body 1a, a hole transport layer 20, a light-emitting layer 30, an electron transport layer 40, and a cathode 50 formed in this order. The conductive layer 12 functions as an anode. The anode (conductive layer 12) and the cathode 50 are connected to a driving power source.

When a voltage supplied from the driving power source is applied, the EL device A transports holes and electrons via the hole transport layer 20 and electron transport layer 40, respectively, and they combine in the light-emitting layer 30 to emit light. The light from the light-emitting layer 30 is extracted through the transparent substrate layer 10 and displayed externally.

The substrate layer 10 is a transparent substrate and may be, for example, a glass substrate, a PET substrate, a PEN substrate, or other film substrate.

The conductive layer 12 functions as a transparent electrode and may be, for example, an ITO electrode or a graphene electrode.

The hole transport layer 20 may be, for example, PEDOT:PSS.

The light-emitting layer 30 may be, for example, Alq₃ (tris-(8-hydroxyquinolinato)aluminum).

The electron transport layer 40 may be, for example, 2-[4-(9,10-di-naphthalen-2-yl-anthracen-2-yl)-phenyl]-1- phenyl-1H-benzimidazole.

The cathode 50 may be, for example, a metal such as Cu.

Although not illustrated, in order to reduce the work function difference with the hole transport layer 20, a tuning layer may be provided between the hole transport layer 20 and the conductive layer 12 as necessary.

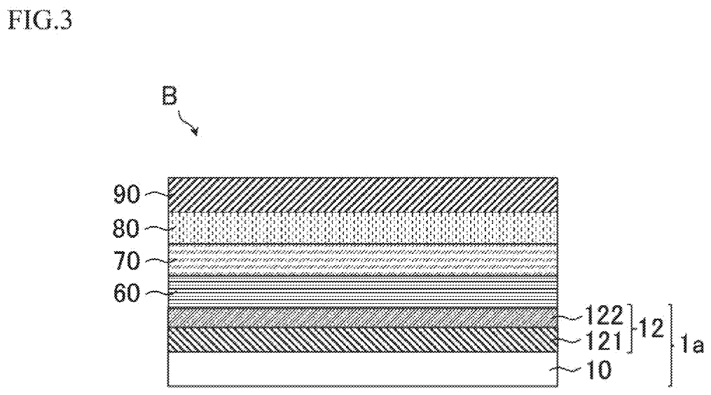

FIG. 3 is a schematic diagram illustrating an example of a solar cell using the laminated body according to the present embodiment.

The solar cell B includes, on the second conductive layer 122 of the laminated body 1a, an electron transport layer 60, an active layer 70, a hole transport layer 80, and an anode 90, in this order. The conductive layer 12 functions as a cathode.

The solar cell B receives light from the light-transmissive substrate layer 10 side, which excites the active layer 70. Electrons and holes generated therein are transported by the electron transport layer 60 and the hole transport layer 80, respectively, and collected by the cathode (conductive layer 12) and the anode 90. Current can then be extracted from an external circuit (not illustrated) connected to the cathode (conductive layer 12) and the anode 90.

The substrate layer 10 is a light-transmissive substrate, which may be, for example, a glass substrate, PET substrate, PEN substrate, or other film substrates.

The conductive layer 12 functions as a transparent electrode, and may be, for example, ITO, ATO (antimony-doped tin oxide), FTO (fluorine-doped tin oxide), AZO (aluminum-doped zinc oxide), or the like.

The electron transport layer 60 may include, for example, LiF₂, TiO₂, or the like.

The active layer 70 may include, for example, C₆₀, CuPc (copper phthalocyanine), or the like.

The anode 90 may include, for example, Al, Cu, or the like.

The hole transport layer 80 may include, for example, PEDOT: PSS, V₂O₅, MoO₃, or the like.

### Laminated Body 2

The second aspect of the laminated body according to the present embodiment includes a support layer, on which a layer containing second conductive particles is formed, and, on the layer containing the second conductive particles, a layer containing first conductive particles is formed. The average particle diameter of the second conductive particles is smaller than that of the first conductive particles. Such a laminated body can suitably be used in components such as EL devices or solar cells, as it can suppress contact resistance and interfacial resistance.

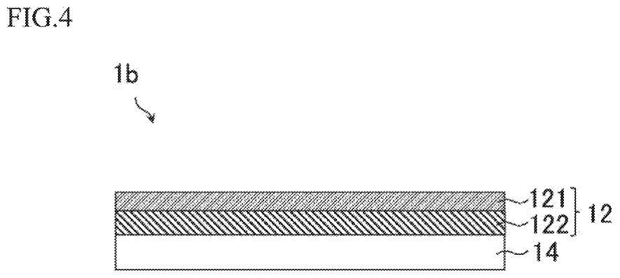

FIG. 4 is a schematic diagram illustrating another example of the laminated body according to the present embodiment.

The laminated body 1b includes, on the support layer 14, a second conductive layer 122 containing the second conductive particles and a first conductive layer 121 containing the first conductive particles, in this order. The average particle diameter of the first conductive particles is larger than that of the second conductive particles (i.e., the average particle diameter of the second conductive particles is smaller than that of the first conductive particles). Unless otherwise specified, the same materials as those used in the laminated body 1b can be appropriately used for the corresponding components.

It is preferable that the first conductive particles, the second conductive particles, or both satisfy the relationship represented by Formula (1) described above.

The material of the support layer 14 is not particularly limited, and materials usable as support layers for the above-described EL devices or solar cells may be used. For example, PEDOT: PSS may be used as the support layer material.

The average particle diameter of the first conductive particles is preferably 40-100 nm, more preferably 40-70 nm, and even more preferably 40-60 nm.

The average particle diameter of the second conductive particles is preferably 5-30 nm, more preferably 5-20 nm, and even more preferably 5 -15 nm.

The ratio of the average particle diameter of the first conductive particles to that of the second conductive particles is preferably 1.3-20, more preferably 1.3-14, and even more preferably 1.3-12.

The thickness of the first conductive layer is preferably 10-1000 nm, more preferably 10-100 nm, and even more preferably 10-20 nm.

The thickness of the second conductive layer is preferably 10-1000 nm, more preferably 10-100 nm, and even more preferably 10-20 nm.

In the laminated body 1b according to the present embodiment, the second conductive particles with a smaller average particle diameter are stacked on the support layer 14 having a fine uneven surface. This increases the contact area between the support layer 14 and the conductive layer 12, thereby reducing the interfacial resistance at the interface between the support layer 14 and the conductive layer 12. Within the conductive layer 12, by stacking the first conductive particles with a larger average particle diameter on top of the second conductive particles with a smaller average particle diameter, the contact area between particles can be increased, thereby reducing the contact resistance between conductive particles. Thus, the laminated body 1b can reduce both interfacial resistance and contact resistance, resulting in high conductivity.

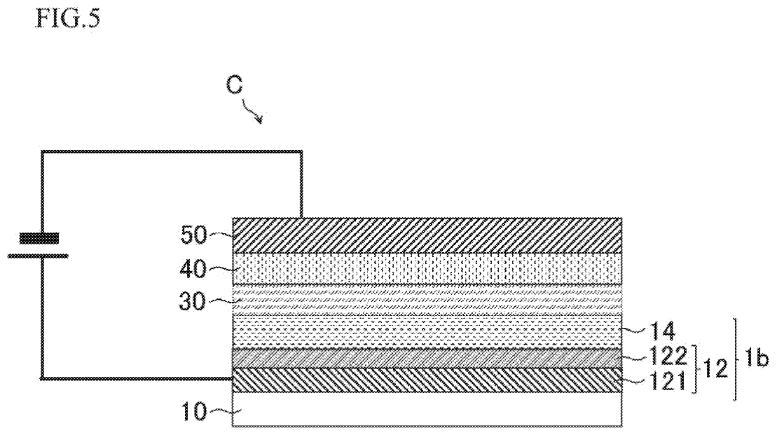

FIG. 5 is a schematic diagram illustrating another example of an EL device using the laminated body according to the present embodiment.

The EL device C includes, on the second conductive layer 122 of the laminated body 1b, a support layer 14, and on the support layer 14, a light-emitting layer 30, an electron transport layer 40, and a cathode 50, in this order. The conductive layer 12 functions as an anode, and the support layer 14 functions as a hole transport layer. The anode (conductive layer 12) and the cathode 50 are connected to a driving power supply. Unless otherwise specified, the same materials as those described above for EL device A may be used for the corresponding components.

In the EL device C, when a voltage supplied from the driving power source is applied, the hole transport layer (support layer 14) and the electron transport layer 40 transport holes and electrons, respectively, which combine in the light-emitting layer 30 to emit light. The emitted light from the light-emitting layer 30 is extracted through the light-transmissive substrate layer 10 and externally displayed.

The support layer 14 may function as a hole transport layer, and the materials described above for the hole transport layer may be used.

The substrate layer 10 may be the same as described above, i.e., a light-transmissive substrate.

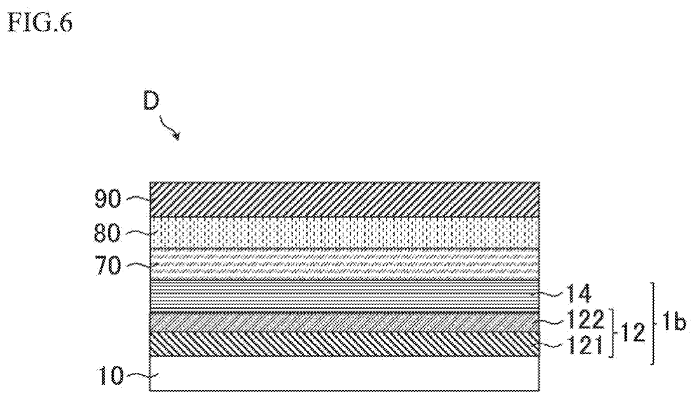

FIG. 6 is a schematic diagram illustrating another example of a solar cell using the laminated body according to the present embodiment.

The solar cell D includes, on the second conductive layer 122 of the laminated body 1b, a support layer 14, and on the support layer 14, an active layer 70, a hole transport layer 80, and an anode 90, in this order. The conductive layer 12 functions as a cathode, and the support layer 14 functions as an electron transport layer. Unless otherwise specified, the same materials as those described above for solar cell B may be used for the corresponding components.

The solar cell D receives light from the light-transmissive substrate layer 10 side, which excites the active layer 70. Electrons and holes generated therein are transported by the electron transport layer (support layer 14) and the hole transport layer 80, respectively, and collected by the cathode (conductive layer 12) and the anode 90. Current can then be extracted from an external circuit (not illustrated) connected to the cathode (conductive layer 12) and the anode 90.

The support layer 14 may function as an electron transport layer, and the materials described above for the electron transport layer may be used.

The substrate layer 10 may be a light-transmissive substrate, similar to the substrate layer described above.

### Method for Manufacturing Conductive Film

According to the present embodiment, a conductive film can be manufactured using the laminated body described above. A preferred method for manufacturing a conductive film including the above-described first conductive layer and second conductive layer includes:
(1) a step of supplying a first solution containing first conductive particles onto the substrate layer or support layer, and drying the solvent contained in the first solution to form the first conductive layer; and
(2) a step of supplying a second solution containing second conductive particles onto the first conductive layer, and drying the solvent contained in the second solution to form the second conductive layer;
wherein the first conductive particles and the second conductive particles have different average particle diameters from each other.

By forming, on the substrate layer or support layer, two layers containing conductive particles having different average particle diameters, a conductive film with reduced contact resistance at the interface can be obtained.

The substrate layer and support layer may be those usable in the laminated body described above.

The layer containing conductive particles can be formed by supplying a dispersion obtained by dispersing the above-described conductive particles in a solvent and drying the solvent.

### (Supplying Step)

As the step of supplying the dispersion onto the substrate layer or support layer (supplying step), a method of applying or spraying the dispersion, in which the conductive particles are dispersed in a solvent, can be employed.

The solvent of the dispersion is not particularly limited, and examples include water, methanol, ethanol, isopropyl alcohol, other alcohols, and mixed solvents thereof. Among these, water and alcohols are preferable, and water is more preferable. That is, the dispersion according to the present embodiment can be suitably used as an aqueous dispersion.

The dispersion may optionally contain other additives as needed.

In particular, when ordinary conductive particles are dispersed in a solvent for a long period, surfactants are typically required to prevent particle aggregation. In contrast, the dispersion used in the present embodiment can maintain long-term dispersion of the conductive particles without adding surfactants. Therefore, the dispersion according to the present embodiment can be substantially free of surfactants, i.e., a surfactant-free dispersion.

Here, the term “surfactant” refers to a substance that adsorbs on the particle surface and enables dispersion of the particles in the medium, such as anionic surfactants, cationic surfactants, and nonionic surfactants.

In the dispersion, the proportion of conductive particles relative to the solvent (volume ratio) is not particularly limited, but is preferably 40% or less. Maintaining this range allows stable monodispersion over a long period.

The dispersion method is not particularly limited; for example, stirring with a stirrer or ultrasonic dispersion using an ultrasonic bath may be employed, either alone or in combination. Among these, using an ultrasonic bath is preferable.

The dispersion may be directly applied onto the substrate layer, or atomized and sprayed onto the substrate layer. The process may be conducted under atmospheric pressure, reduced pressure, or vacuum, with atmospheric pressure being preferable for simplicity.

For example, when manufacturing a conductive film such as an ITO film, the ITO film has high conductivity and transparency and is widely used as a transparent conductive material. Known methods for manufacturing ITO films include sputtering or laser deposition; however, these techniques have difficulty forming uniform thin films on flexible substrates, limiting the performance of ITO with excellent surface properties. In addition, large-scale equipment is often required in such deposition processes, which leaves room for improvement.

In this regard, the dispersion according to the present embodiment exhibits no sedimentation and high dispersibility, allowing simple coating or mist deposition techniques to form ITO thin films on the substrate layer. Moreover, restrictions on substrate material can be relaxed, making it possible to form films on flexible substrates as described above. Further, even when using nano-level ITO particles (ITO nanoparticles), high crystallinity and monodispersity can be stably maintained, enabling high-level control of surface properties such as conductivity and transparency of the thin film.

As a method for atomization, any method that can convert the dispersion into a mist is acceptable. Known techniques for generating mist may be used, including pressurized, rotating disk, ultrasonic, electrostatic, orifice vibration, and steam methods. In the present embodiment, since the dispersion contains ITO particles, a physical atomization method is preferable. This facilitates temperature and droplet size control and allows highly controlled handling of the dispersion without issues such as film distortion encountered in sol-gel methods.

In the misting process, a carrier gas may be used to transport the mist to the subsequent contact step. Inert gases such as argon, helium, or nitrogen may be used as the carrier gas.

The misting process may further include a step of homogenizing the mist using a mist trap or a retention step to control the residence time (retention portion) of the mist.

Spraying techniques may include ultrasonic spraying, mist CVD, Sonia-source method, and hot-wall method, which may be selected considering the film thickness and droplet size of the conductive film to be formed on the substrate layer.

Furthermore, by applying or spraying the dispersion onto a masked substrate layer or support layer, fine pattern formation can be achieved. This is particularly suitable when forming thin films with ITO nanoparticles, enabling high-precision dimensional control. For example, when water is used as the solvent of the dispersion, a hydrophobic masking material (water-repellent film) is preferably used as the mask, further enhancing patterning precision.

### (Drying Step)

The drying step involves drying the dispersion supplied on the substrate layer or support layer, for example by infrared irradiation or heating, to volatilize the solvent and form a conductive film on the substrate surface. The heating temperature may be set considering the solvent's boiling point, the softening point of the substrate, and the effects on other properties of the conductive film. The softening point of the substrate refers to the temperature at which the substrate begins to soften and deform upon heating, and can be determined, for example, according to JIS K7191-1.

After the drying step, if necessary, a step of slowly cooling the substrate on which the conductive film has been formed (slow cooling step) or a UV irradiation step for the purpose of modifying the base material, such as imparting hydrophilicity, may be carried out.

In the manufacturing method according to this embodiment, layers containing conductive particles may be formed sequentially on a substrate layer, or layers containing conductive particles may be formed sequentially on a support layer.

### Method 2 for Manufacturing Conductive Film

When layers containing conductive particles are sequentially formed on a substrate layer, the process involves supplying the above-mentioned first solution onto the substrate layer and drying the solvent contained in the first solution to form a first layer, and supplying a second solution onto the first layer and drying the solvent contained in the second solution to form a second layer (see FIG. 1). In this case, the details of the manufacturing method already described can be used for each process unless otherwise specified.

### Method 3 for Manufacturing Conductive Film

When a layer containing conductive particles is sequentially formed on a support layer, the process involves supplying the above-mentioned the second solution onto the support layer and drying the solvent contained in the second solution to form the second layer, and supplying the first solution onto the second layer and drying the solvent contained in the first solution to form the first layer (see FIG. 4). In this case, the details of the manufacturing method already described can be used for each process unless otherwise specified.

The conductive film obtained by the manufacturing method of the present embodiment has a high film density and can reduce contact resistance between the upper and lower layers.

### Reference Signs List

1a, 1b . . . laminated body; 10 . . . substrate layer; 12, 121, 122 . . . conductive layer; 14 . . . support layer; 20, 80 . . . hole transport layer; 30 . . . light-emitting layer; 40, 60 . . . electron transport layer; 50 . . . cathode; 90 . . . anode; 70 . . . active layer; A, C . . . EL device; B, D . . . solar cell

What is claimed is:

1. A laminated body comprising:
a substrate layer;
a first layer disposed on the substrate layer, the first layer containing first conductive particles as a main component; and
a second layer disposed on the first layer, the second layer containing second conductive particles as a main component,
wherein an average particle diameter of the first conductive particles is larger than an average particle diameter of the second conductive particles.

2. The laminated body according to claim 1,
wherein the first conductive particles and/or the second conductive particles satisfy the relationship represented by the following formula (1):
16×S/P²≤0.330 (1)
where S represents a particle area in a TEM image, and P represents a perimeter of the particle.

3. The laminated body according to claim 1,
wherein the first conductive particles are ITO particles.

4. The laminated body according to claim 1,
wherein the second conductive particles are ITO particles.

5. A laminated body comprising:
a support layer;
a first layer disposed on the support layer, the first layer containing second conductive particles as a main component; and
a second layer disposed on the first layer, the second layer containing first conductive particles as a main component, wherein an average particle diameter of the second conductive particles is smaller than an average particle diameter of the first conductive particles.

6. The laminated body according to claim 5, wherein the first conductive particles and/or the second conductive particles satisfy the relationship represented by the following formula (1):
16×S/P²≤0.330 (1)
where S represents a particle area in a TEM image, and P represents a perimeter of the particle.

7. A method for producing a laminated body including a first layer and a second layer, comprising:
supplying a first solution containing first conductive particles onto a substrate layer or a support layer, and drying a solvent contained in the first solution to form the first layer containing the first conductive particles as a main component; and
supplying a second solution containing second conductive particles onto the first layer, and drying a solvent contained in the second solution to form the second layer containing the second conductive particles as a main component,
wherein the first conductive particles and the second conductive particles have different average particle diameters from each other.

8. The method for producing a laminated body according to claim 7,
wherein the first solution is supplied onto the substrate layer, and
wherein the average particle diameter of the first conductive particles is larger than the average particle diameter of the second conductive particles.

9. The method for producing a laminated body according to claim 8,
wherein a ratio of the average particle diameter of the first conductive particles to the average particle diameter of the second conductive particles is 1.3 to 20.

10. The method for producing a laminated body according to claim 8,
wherein the first conductive particles or the second conductive particles satisfy the relationship represented by the following formula (1):
16×S/P²≤0.330 (1)
where S represents a particle area in a TEM image, and P represents a perimeter of the particle.

11. The method for producing a laminated body according to claim 7,
wherein the first solution is supplied onto the support layer, and
wherein the average particle diameter of the first conductive particles is smaller than the average particle diameter of the second conductive particles.

12. The method for producing a laminated body according to claim 10,
wherein a ratio of the average particle diameter of the second conductive particles to the average particle diameter of the first conductive particles is 1.3 to 20.

13. The method for producing a laminated body according to claim 11,
wherein the first conductive particles or the second conductive particles satisfy the relationship represented by the following formula (1):
16×S/P²≤0.330 (1)
where S represents a particle area in a TEM image, and P represents a perimeter of the particle.

14. The method for producing a laminated body according to claim 7,
wherein the first solution is atomized into a mist and supplied onto the substrate layer.

15. The method for producing a laminated body according to claim 7,
wherein the second solution is atomized into a mist and supplied onto the substrate layer.
